(19) United States
(12) Patent Application Publication
(10) Pub. No.: US 2016/0187777 A1
(43) Pub. Date: Jun. 30, 2016

(54) COMPOSITION AND PATTERN-FORMING METHOD

(71) Applicant: JSR CORPORATION, Tokyo (JP)

(72) Inventors: Hisashi NAKAGAWA, Tokyo (JP); Ryuichi SAITO, Tokyo (JP); Kenji FUJITA, Tokyo (JP); Shunsuke KURITA, Tokyo (JP); Tatsuya SAKAI, Tokyo (JP)

(73) Assignee: JSR CORPORATION, Tokyo (JP)

(21) Appl. No.: 15/064,920

(22) Filed: Mar. 9, 2016

Related U.S. Application Data
(63) Continuation of application No. PCT/JP2014/071589, filed on Aug. 18, 2014.

(30) Foreign Application Priority Data
Sep. 11, 2013 (JP) 2013-188750

(51) Int. Cl. G03F 7/11; H01L 21/027; H01L 21/3065; H01L 21/308; C09D 1/00; H01L 21/311

(52) U.S. Cl. CPC G03F 7/11; C09D 1/00; H01L 21/31116; H01L 21/31144; H01L 21/3065; H01L 21/3081; H01L 21/3086; H01L 21/0276

(57) ABSTRACT

A composition includes a metal compound and a solvent. The metal compound includes: a plurality of metal atoms of titanium, tantalum, zirconium, tungsten or a combination thereof; oxygen atoms each crosslinking the metal atoms; and polydentate ligands each coordinating to the metal atom. An absolute molecular weight of the metal compound as determined by static light scattering is no less than 8,000 and no greater than 50,000. A pattern-forming method includes applying the composition on an upper face side of a substrate to form an inorganic film. A resist pattern is formed on an upper face side of the inorganic film. The inorganic film and the substrate are dry-etched, by each separate etching operation, using the resist pattern as a mask such that the substrate has a pattern.

### CROSS-REFERENCE TO RELATED APPLICATIONS

The present application is a continuation application of International Application No. PCT/JP2014/071589, filed Aug. 18, 2014, which claims priority to Japanese Patent Application No. 2013-188750, filed Sep. 11, 2013. The contents of these applications are incorporated herein by reference in their entirety.

### BACKGROUND OF THE INVENTION

1. Field of the Invention

The present invention relates to a composition and a pattern-forming method.

2. Discussion of the Background

Miniaturization of semiconductor devices and the like has been accompanied by the progress of a reduction in processing size by utilizing a multilayer resist process in order to achieve a higher degree of integration. In the multilayer resist process, an inorganic film is formed on a substrate using a composition for forming an inorganic film, and then a resist pattern is formed on the inorganic film using an organic material that differs in etching rate from the inorganic film. Next, the resist pattern is transferred to the inorganic film by dry-etching, and further dry-etching is carried out to transfer the pattern to the substrate, whereby a desirably patterned substrate is obtained (see Japanese Unexamined Patent Application, Publication Nos. 2001-284209, 2010-85912 and 2008-39811). Recently, in addition to compositions containing a silicon compound, a composition which contains a metal-containing compound and can exhibit superior etching selectivity with respect to a silicon dioxide film provided adjacent to the inorganic film and also with respect to a resist underlayer film which is an organic film has been studied as the composition for forming an inorganic film (see Japanese Unexamined Patent Application (Translation of PCT Application), Publication No. 2005-537502).

### SUMMARY OF THE INVENTION

According to one aspect of the present invention, a composition includes a metal compound and a solvent. The metal compound includes: a plurality of metal atoms of titanium, tantalum, zirconium, tungsten or a combination thereof; oxygen atoms each crosslinking the metal atoms; and polydentate ligands each coordinating to the metal atom. An absolute molecular weight of the metal compound as determined by static light scattering is no less than 8,000 and no greater than 50,000.

According to another aspect of the present invention, a pattern-forming method includes applying the composition on an upper face side of a substrate to form an inorganic film. A resist pattern is formed on an upper face side of the inorganic film. The inorganic film and the substrate are dry-etched, by each separate etching operation, using the resist pattern as a mask such that the substrate has a pattern.

### DESCRIPTION OF THE EMBODIMENTS

According to an embodiment of the invention made for solving the aforementioned problems, a composition for forming an inorganic film for a multilayer resist process contains: a metal compound (hereinafter, may be also referred to as “(A) metal compound” or “metal compound (A)”) containing a plurality of metal atoms of at least one element type selected from the group consisting of titanium, tantalum, zirconium and tungsten, oxygen atoms each crosslinking the metal atoms, and polydentate ligands each coordinating to the metal atom; and a solvent (hereinafter, may be also referred to as “(B) solvent” or “solvent (B)”), wherein the absolute molecular weight of the metal compound (A) as determined by static light scattering is no less than 8,000 and no greater than 50,000.

According to another embodiment of the invention made for solving the aforementioned problems, a pattern-forming method includes the steps of: forming an inorganic film on the upper face side of a substrate; forming a resist pattern on the upper face side of the inorganic film; and dry-etching at least the inorganic film and the substrate, by each separate etching operation, using the resist pattern as a mask such that the substrate has a pattern, wherein the inorganic film is formed from the composition for forming an inorganic film for a multilayer resist process.

The term “organic group” as referred to herein means a group having at least one carbon atom.

According to the composition for forming an inorganic film for a multilayer resist process and the pattern-forming method of the embodiments of the present invention, an inorganic film that is superior in resist pattern formability and etching selectivity can be formed while both superior removability with a cleaning solvent and superior volatilization inhibitory ability are exhibited. Specifically, a coating film left after drying the composition can be removed through dissolution in a cleaning solvent used in edge-and-back rinsing for cleaning the edge and the back face of the substrate. Moreover, since an inorganic film-derived component is less likely to be volatilized from the coating film during the baking for forming the inorganic film, contamination of a chamber can be avoided, and consequently pattern formation by the multilayer resist process can be stably carried out. Therefore, these can be highly suitably used in production processes of LSIs in which further progress of miniaturization is expected in the future, in particular for forming fine contact holes and the like. Hereinafter, the embodiments will be explained in detail.

### Composition for Forming Inorganic Film for Multilayer Resist Process

The composition for forming an inorganic film for a multilayer resist process (hereinafter, may be also merely referred to as “inorganic film-forming composition”) according to an embodiment of the present invention contains the metal compound (A) and the solvent (B). The inorganic film-forming composition may contain a crosslinking accelerator (hereinafter, may be also referred to as “(C) crosslinking accelerator” or “crosslinking accelerator (C)”) as a favorable component, and may contain other optional component within a range not leading to impairment of the effects of the present invention.

Hereinafter, each component will be described.

### (A) Metal Compound

The metal compound (A) contains a plurality of metal atoms of at least one element type selected from the group consisting of titanium, tantalum, zirconium and tungsten (hereinafter, may be also referred to as “specific metal atoms”), oxygen atoms each crosslinking the metal atoms (hereinafter, may be also referred to as “crosslinking oxygen atoms”), and polydentate ligands each coordinating to the metal atom, wherein the absolute molecular weight of the metal compound (A) as determined by static light scattering is no less than 8,000 and no greater than 50,000.

As described above, the metal compound (A) is a complex (polynuclear complex) containing the specific metal atoms, the crosslinking oxygen atoms, and the polydentate ligands each coordinating to the specific metal atom.

Due to containing the metal compound (A), the inorganic film-forming composition can form an inorganic film exhibiting superior resist pattern formability and etching selectivity, and is superior in both removability with a cleaning solvent and volatilization inhibitory ability.

Hereinafter, the specific metal atoms, the crosslinking oxygen atoms and the polydentate ligands, which constitute the metal compound (A), will be described in this order.

### Specific Metal Atoms

The metal compound (A) contains a plurality of metal atoms. The metal atoms are metal atoms of at least one element type selected from the group consisting of titanium, tantalum, zirconium and tungsten. Since the metal atoms contained in the metal compound (A) are metal atoms of the element described above, the inorganic film formed from the inorganic film-forming composition is superior in resist pattern formability and etching selectivity. The specific metal atoms may consist of either one element type or two or more element types of atoms; however, the specific metal atoms preferably consist of one element type of atoms in light of the etching rate that is desirably uniform over a plane at a nanometer-order level, in transfer processing to the inorganic film by etching after the fine pattern formation.

The metal atom is preferably a titanium atom or a zirconium atom. When the metal atom of the metal compound (A) in the inorganic film-forming composition is the titanium atom or the zirconium atom, more favorable etching selectivity for the inorganic film with respect to the substrate and the resist underlayer film may be achieved.

The metal compound (A) may contain other metal atom than the specific metal atoms as long as the amount of the other metal atom is so small that the effects of the present invention are not impaired.

### Crosslinking Oxygen Atoms

The metal compound (A) contains oxygen atoms each crosslinking the metal atoms. Since the metal compound (A) contains the oxygen atoms each crosslinking the specific metal atoms, the metal compound (A) can be a stable polynuclear metal compound, and consequently the inorganic film formed from the inorganic film-forming composition is superior in resist pattern formability and etching selectivity. One crosslinking oxygen atom may bond to one metal atom, or a plurality of crosslinking oxygen atoms may bond to one metal atom; however, it is preferred that the metal compound (A) principally has a structure in which two crosslinking oxygen atoms bond to a metal atom. When the metal compound (A) principally has the structure in which two crosslinking oxygen atoms bond to the metal atom, the metal compound (A) may have a more linear structure, e.g., -M-O-M-O—, wherein M represents one of the specific metal atoms, leading to an improvement of the solubility, and consequently the removability with a cleaning solvent of the inorganic film-forming composition can be improved. The phrase “principally has a structure” as referred to means that no less than 50 mol %, preferably no less than 70 mol %, more preferably no less than 90 mol %, and particularly preferably no less than 95 mol % of the entire metal atoms constituting the metal compound (A) have the structure described above.

The ligand crosslinking the metal atoms in the metal compound (A) may contain other bridging ligand in addition to the crosslinking oxygen atoms as long as the amount of the other bridging ligand is so small that the effects of the present invention are not impaired. The other bridging ligand is exemplified by a peroxide ligand (—O—O—), and the like.

### Polydentate Ligands

The metal compound (A) contains polydentate ligands each coordinating to the metal atom. Since the metal compound (A) contains such polydentate ligands, the solubility thereof can be increased, and consequently the inorganic film-forming composition may exhibit superior removability with a cleaning solvent.

The polydentate ligand is preferably derived from at least one selected from the group consisting of a hydroxyacid ester, a β-diketone, a β-keto ester, a β-dicarboxylic acid ester and a hydrocarbon having a π bond. When the polydentate ligand is the ligand described just above, the removability with a cleaning solvent of the inorganic film-forming composition can be more improved. These compounds typically form a polydentate ligand on its own, or in the form of an anion which is formed through acceptance of one electron.

The hydroxyacid ester is not particularly limited as long as the hydroxyacid ester is a carboxylic acid ester having a hydroxy group, and examples thereof include a compound represented by the following formula (2), and the like.

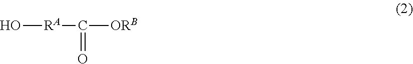

In the above formula (2), R^{A} represents a divalent organic group having 1 to 20 carbon atoms; and R^{B} represents a monovalent organic group having 1 to 20 carbon atoms.

The divalent organic group represented by R^{A} is exemplified by: a monovalent hydrocarbon group having 1 to 20 carbon atoms; a group (a) that is obtained from the hydrocarbon group by incorporating a divalent hetero atom-containing group between adjacent carbon atoms or at the end on the atomic bonding side; a group obtained from the hydrocarbon group or the group (a) by substituting a part or all of hydrogen atoms included in the hydrocarbon group or the group (a) with a monovalent hetero atom-containing group; and the like.

Examples of the hetero atom included in the monovalent hetero atom-containing group or the divalent hetero atom-containing group include an oxygen atom, a nitrogen atom, a sulfur atom, a silicon atom, a phosphorus atom, and the like.

Examples of the divalent hetero atom-containing group include —O—, —S—, —CO—, —CS—, —NR′—, a combination thereof, and the like, wherein R′ represents a hydrogen atom or a monovalent hydrocarbon group having 1 to 10 carbon atoms.

Examples of the monovalent hetero atom-containing group include a hydroxy group, a sulfanyl group (—SH), an amino group, a cyano group, a carboxy group, a keto group (═O), and the like.

Examples of the monovalent organic group represented by R^{B} include groups obtained from the groups exemplified in connection with the divalent organic group represented by R^{A} by incorporating one hydrogen atom thereinto, and the like.

R^{A} represents preferably a divalent hydrocarbon group, more preferably an alkanediyl group, a cycloalkanediyl group or an arenediyl group, still more preferably a methanediyl group, an ethanediyl group, a cyclohexanediyl group or a benzenediyl group, and particularly preferably an ethanediyl group.

R^{B} represents preferably a monovalent hydrocarbon group, more preferably an alkyl group, still more preferably a methyl group, an ethyl group, a propyl group or a butyl group, and particularly preferably an ethyl group.

Examples of the hydroxyacid ester include glycolic acid esters, lactic acid esters, 2-hydroxycyclohexane-1-carboxylic acid esters, salicylic acid esters, and the like. Of these, the lactic acid esters are preferred, and ethyl lactate is more preferred.

The β-diketone is not particularly limited as long as the β-diketone is a compound having a 1,3-diketo structure, and examples thereof include a compound represented by the following formula (3), and the like.

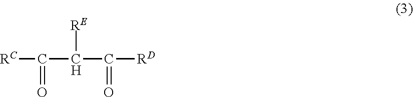

In the above formula (3), R^{C} and R^{D} each independently represent a monovalent organic group having 1 to 20 carbon atoms; and R^{E} represents a hydrogen atom or a monovalent organic group having 1 to 20 carbon atoms.

The monovalent organic group having 1 to 20 carbon atoms which may be represented by R^{C}, R^{D} or R^{E} is exemplified by groups similar to those exemplified in connection with the monovalent organic group represented by R^{B} in the above formula (2), and the like.

R^{C} and R^{D} each independently represent preferably a monovalent hydrocarbon group, more preferably an alkyl group, still more preferably a methyl group, an ethyl group, a propyl group or a butyl group, and particularly preferably a methyl group.

R^{E} represents preferably a hydrogen atom or a monovalent hydrocarbon group, more preferably a hydrogen atom or an alkyl group, still more preferably a hydrogen atom or a methyl group, and particularly preferably a hydrogen atom.

Examples of the β-diketone include 2,4-pentanedione, 3-methyl-2,4-pentanedione, 3-ethyl-2,4-pentanedione, and the like. Of these, 2,4-pentanedione and 3-methyl-2,4-pentanedione are preferred, and 2,4-pentanedione is more preferred.

The β-keto ester is not particularly limited as long as the β-keto ester is a compound having a ketonic carbonyl group at a position β in the carboxylic acid ester, and examples thereof include a compound represented by the following formula (4), and the like.

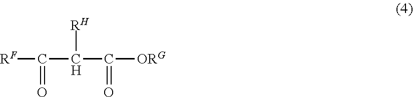

In the above formula (4), R^{F} and R^{G} each independently represent a monovalent organic group having 1 to 20 carbon atoms; and R^{H} represents a hydrogen atom or a monovalent organic group having 1 to 20 carbon atoms.

The monovalent organic group having 1 to 20 carbon atoms which may be represented by R^{F}, R^{G} or R^{H} is exemplified by groups similar to those exemplified in connection with the monovalent organic group represented by R^{B} in the above formula (2), and the like.

R^{F} represents preferably a monovalent hydrocarbon group or a carbonyloxyhydrocarbon group-substituted hydrocarbon group, more preferably an alkyl group, an aryl group or an alkoxycarbonylalkyl group, still more preferably a methyl group, a phenyl group or a methoxycarbonylmethyl group, and particularly preferably a methyl group.

R^{G} represents preferably a monovalent hydrocarbon group, more preferably an alkyl group, still more preferably a methyl group, an ethyl group, a propyl group or a butyl group, and particularly preferably an ethyl group.

R^{H} represents preferably a hydrogen atom or a monovalent hydrocarbon group, more preferably a hydrogen atom or an alkyl group, still more preferably a hydrogen atom or a methyl group, and particularly preferably a hydrogen atom.

Examples of the β-keto ester include acetoacetic acid esters, α-alkyl-substituted acetoacetic acid esters, β-ketopentanoic acid esters, benzoylacetic acid esters, 1,3-acetonedicarboxylic acid esters, and the like. Of these, the acetoacetic acid esters are preferred, and ethyl acetoacetate is more preferred.

The β-dicarboxylic acid ester is not particularly limited as long as the β-dicarboxylic acid ester is a compound having a structure in which two ester groups (—COOR) bond to a single carbon atom, and examples thereof include a compound represented by the following formula (5), and the like.

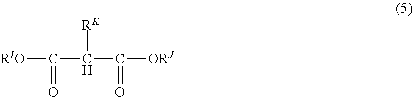

In the above formula (5), R^{I} and R^{J} each independently represent a monovalent organic group having 1 to 20 carbon atoms; and R^{K} represents a hydrogen atom or a monovalent organic group having 1 to 20 carbon atoms.

The monovalent organic group having 1 to 20 carbon atoms which may be represented by R^{I}, R^{J} or R^{K} is exemplified by groups similar to those exemplified in connection with the monovalent organic group represented by R^{B} in the above formula (2), and the like.

R^{I} and R^{J} each independently represent preferably a monovalent hydrocarbon group, more preferably an alkyl group, still more preferably a methyl group, an ethyl group, a propyl group or a butyl group, and particularly preferably an ethyl group.

R^{K} represents preferably a hydrogen atom or a monovalent hydrocarbon group, more preferably a hydrogen atom, an alkyl group, a cycloalkyl group or an aryl group, still more preferably a hydrogen atom or an alkyl group, and particularly preferably a hydrogen atom.

Examples of the β-dicarboxylic acid ester include malonic acid diesters, α-alkyl-substituted malonic acid diesters, α-cycloalkyl-substituted malonic acid diesters, α-aryl-substituted malonic acid diesters, and the like. Of these, malonic acid diesters are preferred, and diethyl malonate is more preferred.

Examples of the hydrocarbon having a π bond include:

chain olefins such as ethylene and propylene;

cyclic olefins such as cyclopentene, cyclohexene and norbornene;

chain dienes such as butadiene and isoprene;

cyclic dienes such as cyclopentadiene, methylcyclopentadiene, pentamethylcyclopentadiene, cyclohexadiene and norbornadiene;

aromatic hydrocarbons such as benzene, toluene, xylene, hexamethylbenzene, naphthalene and indene; and the like.

Of these, the cyclic dienes are preferred, and cyclopentadiene is more preferred. Cyclopentadiene typically accepts one electron to form a cyclopentadienyl anion that is a polydentate ligand.

The number of polydentate ligand per metal atom is preferably 1 or 2, and more preferably 1. It is to be noted that the number of polydentate ligand means an average number per metal atom.

The metal compound (A) may contain other ligand in addition to the bridging ligand and the polydentate ligands. The other ligand is exemplified by a ligand represented by X in a compound represented by formula (1) described later, and the like.

The lower limit of the absolute molecular weight of the metal compound (A) as determined by static light scattering is 8,000, preferably 10,000, more preferably 12,000, still more preferably 14,000, and particularly preferably 16,000. The upper limit of the absolute molecular weight is 50,000, preferably 46,000, more preferably 40,000, still more preferably 32,000, and particularly preferably 28,000.

When the absolute molecular weight of the metal compound (A) falls within the above range, the inorganic film-forming composition may exhibit a higher level of both the removability with a cleaning solvent and the volatilization inhibitory ability.

When the absolute molecular weight of the metal compound (A) is less than the lower limit, the volatilization inhibitory ability of the inorganic film-forming composition tends to deteriorated. When the absolute molecular weight of the metal compound (A) is greater than the upper limit, the removability with a cleaning solvent of the inorganic film-forming composition tends to deteriorated.

The absolute molecular weight of the metal compound (A) as determined by static light scattering is a value determined using the following apparatus under the following conditions. It is to be noted that a procedure for the determination is exemplified by: a procedure that involves charging a sample solution into a quartz cell, followed by placing the quartz cell in an apparatus, as is the case of using the apparatus described below; a procedure that involves using a multiangle laser light scattering (MALLS) detector, in which a sample solution is injected into a flow cell; and the like, and any of these procedures may be used to determine the absolute molecular weight of the compound (A):

apparatus: light scattering measurement apparatus (“ALV-5000” available from ALV-GmbH, Germany);

measurement concentration: 4 levels of 2.5% by mass, 5.0% by mass, 7.5% by mass, 10.0% by mass;

standard liquid: toluene; and

measurement temperature: 23° C.

The refractive index of the solution and the density of the solution which are necessary for the calculation of the absolute molecular weight are determined using the following apparatuses:

apparatus for determination of the refractive index of the solution: refractometer (“RA-500” available from Kyoto Electronics Manufacturing Co., Ltd.); and

apparatus for determination of the density of the solution: density/specific gravity meter (“DA-100” available from Kyoto Electronics Manufacturing Co., Ltd.).

### Synthesis Method of Metal Compound (A)

The metal compound (A) may be obtained by, for example, hydrolytic condensation of a compound represented by the following formula (1).

[MLₐX_{b}] (1)

In the above formula (1), M represents a titanium atom, a tantalum atom, a zirconium atom or a tungsten atom; L represents a polydentate ligand; a is an integer of 1 to 3, wherein in a case where a is no less than 2, a plurality of Ls may be identical or different; X represents a halogen ligand, a hydroxo ligand, a carboxy ligand, an alkoxy ligand, a carboxylate ligand or an amido ligand; and b is an integer of 2 to 6, wherein a plurality of Xs may be identical or different, and wherein a value of (a×2+b) is no greater than 6.

The polydentate ligand represented by L is exemplified by the polydentate ligands exemplified in connection with the polydentate ligand contained in the metal compound (A), and the like.

In the above formula (1), a is preferably 1 or 2, and more preferably 1.

Examples of the halogen ligand which may be represented by X include a fluorine ligand, a chlorine ligand, a bromine ligand, an iodine ligand, and the like. Of these, the chlorine ligand is preferred.

Examples of the alkoxy ligand which may be represented by X include a methoxy ligand (OMe), an ethoxy ligand (OEt), a n-propoxy ligand (n-OPr), an i-propoxy ligand (i-OPr), a n-butoxy ligand (n-OBu), and the like. Of these, the ethoxy ligand, the i-propoxy ligand and the n-butoxy ligand are preferred.

Examples of the carboxylate ligand which may be represented by X include a formate ligand (OOCH), an acetate ligand (OOCMe), a propionate ligand (OOCEt), a butyrate ligand (OOCPr), and the like. Of these, the acetate ligand is preferred.

Examples of the amido ligand which may be represented by X include an unsubstituted amido ligand (NH₂), a methylamido ligand (NHMe), a dimethylamido ligand (NMe₂), a diethylamido ligand (NEt₂), a dipropylamido ligand (NPr₂), and the like. Of these, the dimethylamido ligand and the diethylamido ligand are preferred.

In the above formula (1), b is preferably an integer of 2 to 4, more preferably 2 or 3, and still more preferably 2. When b is 2, the formed metal compound (A) may have a more linear structure, and consequently the stability of the inorganic film-forming composition to a cleaning solvent can be improved.

The hydrolytic condensation reaction of the compound may be carried out, for example, in a solvent in the presence of water. The amount of water in the hydrolytic condensation reaction with respect to the compound is preferably 1 to 20-fold moles, and more preferably 1 to 15-fold moles. Moreover, in light of the acceleration of the hydrolysis reaction and the condensation reaction, the hydrolytic condensation reaction may be carried out in the presence of an acid and/or acid anhydride such as maleic anhydride in addition to water.

The solvent which may be used in the reaction is not particularly limited, and the solvent is exemplified by an alcohol solvent, a ketone solvent, an amide solvent, an ether solvent, an ester solvent, a hydrocarbon solvent, and the like. Examples of the solvent include solvents exemplified later in connection with the solvent (B), and the like. Of those solvents, alcohol solvents, ether solvents, ester solvents and hydrocarbon solvents are preferred, monohydric aliphatic alcohols, alkylene glycol monoalkyl ethers, hydroxyacid esters, alkylene glycol monoalkyl ether carboxylates, lactones, cyclic ethers and aromatic hydrocarbons are more preferred, monohydric aliphatic alcohols having 2 or more carbon atoms, alkylene glycol monoalkyl ethers having 6 or more carbon atoms, hydroxyacid esters having 4 or more carbon atoms, alkylene glycol monoalkyl ether carboxylates having 6 or more carbon atoms, lactones having 4 or more carbon atoms, cyclic ethers having 4 or more carbon atoms and aromatic hydrocarbons having 7 or more carbon atoms are still more preferred, and ethanol, n-butanol, propylene glycol monomethyl ether, propylene glycol monoethyl ether, propylene glycol monopropyl ether, ethyl lactate, propylene glycol monomethyl ether acetate, γ-butyrolactone, tetrahydrofuran and toluene are particularly preferred. The solvent used in the reaction may be directly used as the solvent (B) of the inorganic film-forming composition without removal thereof after the reaction.

The temperature in the reaction is preferably 0° C. to 150° C., and more preferably 10° C. to 120° C. The time period of the reaction is preferably 30 min to 24 hrs, more preferably 1 hour to 20 hrs, and still more preferably 2 hrs to 15 hrs.

The polydentate ligand such as ethyl lactate may be added to the reaction mixture obtained in the hydrolytic condensation reaction.

Alternatively, the metal compound (A) can be synthesized not only by the method in which the abovementioned compound is hydrolyzed and condensed, but also by, for example: a method that involves reacting a metal compound having an alkoxy ligand, a metal compound having a halogen ligand, or the like with a polydentate ligand or the like, for example, in a solvent in the presence of water; a method that involves reacting a metal compound containing metal atoms and crosslinking oxygen atoms with polydentate ligands in a solvent; or the like.

### (B) Solvent

Any solvent that is capable of dissolving or dispersing the metal compound (A) may be used as the solvent (B).

The solvent (B) is exemplified by an alcohol solvent, a ketone solvent, an amide solvent, an ether solvent, an ester solvent, and the like. These solvents may be used either of one type alone, or as a mixture of two or more types thereof. The solvent used in the reaction for the synthesis of the metal compound (A) described above may be directly used as the solvent (B) without removal thereof.

Examples of the alcohol solvent include:

monohydric aliphatic alcohols such as methanol, ethanol, n-propanol, iso-propanol, n-butanol, iso-butanol, sec-butanol, tert-butanol, n-pentanol, iso-amyl alcohol, 2-methylbutanol, sec-pentanol, tert-pentanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol and sec-heptadecyl alcohol;

monohydric alicyclic alcohols such as cyclohexanol, methylcyclohexanol and 3,3,5-trimethylcyclohexanol;

aromatic alcohols such as benzyl alcohol and phenethyl alcohol;

monohydric, ether group- or keto group-containing alcohols such as 3-methoxybutanol, furfuryl alcohol and diacetone alcohol;

polyhydric alcohols such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol and tripropylene glycol;

alkylene glycol monoalkyl ethers such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, propylene glycol monomethyl ether, propylene glycol monoethyl ether, propylene glycol monopropyl ether and propylene glycol monobutyl ether;

ether group-containing alkylene glycol monoalkyl ethers such as diethylene glycol monomethyl ether, diethylene glycol monoethyl ether, diethylene glycol monopropyl ether, diethylene glycol monobutyl ether, diethylene glycol monohexyl ether, dipropylene glycol monomethyl ether, dipropylene glycol monoethyl ether and dipropylene glycol monopropyl ether; and the like.

Examples of the ketone solvent include:

chain ketones such as acetone, methyl ethyl ketone, methyl n-propyl ketone, methyl n-butyl ketone, diethyl ketone, methyl iso-butyl ketone, methyl n-pentyl ketone, ethyl n-butyl ketone, methyl n-hexyl ketone, di-iso-butyl ketone and trimethylnonanone;

cyclic ketones such as cyclopentanone, cyclohexanone, cycloheptanone, cyclooctanone and methylcyclohexanone;

aromatic ketones such as acetophenone and phenyl ethyl ketone;

γ-diketones such as acetonylacetone; and the like.

Examples of the amide solvent include:

chain amides such as N-methylformamide, N,N-dimethylformamide, N,N-diethylformamide, acetamide, N-methylacetamide, N,N-dimethylacetamide and N-methylpropionamide;

cyclic amides such as N-methylpyrrolidone and N,N′-dimethylimidazolidinone; and the like.

Examples of the ether solvent include:

dialiphatic ethers such as diethyl ether and dipropyl ether;

aromatic-aliphatic ethers such as anisole and phenyl ethyl ether;

diaromatic ethers such as diphenyl ether;

cyclic ethers such as tetrahydrofuran, tetrahydropyran and dioxane; and the like.

Examples of the ester solvent include:

monocarboxylic acid esters such as methyl acetate, ethyl acetate, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, ethyl propionate, n-butyl propionate, iso-amyl propionate, methyl acetoacetate and ethyl acetoacetate;

dicarboxylic acid esters such as diethyl oxalate, di-n-butyl oxalate, diethyl malonate, dimethyl phthalate and diethyl phthalate;

alkylene glycol monoalkyl ether carboxylates such as ethylene glycol monomethyl ether acetate, ethylene glycol monoethyl ether acetate, ethylene glycol monopropyl ether acetate, propylene glycol monomethyl ether acetate, propylene glycol monoethyl ether acetate, propylene glycol monopropyl ether acetate, propylene glycol monobutyl ether acetate and propylene glycol monomethyl ether propionate;

ether group-containing alkylene glycol monoalkyl ether carboxylates such as diethylene glycol monomethyl ether acetate, diethylene glycol monoethyl ether acetate, diethylene glycol mono-n-butyl ether acetate, dipropylene glycol monomethyl ether acetate, dipropylene glycol monoethyl ether acetate and diethylene glycol monomethyl ether propionate;

hydroxyacid esters such as methyl glycolate, ethyl glycolate, methyl lactate, ethyl lactate, n-butyl lactate and n-amyl lactate;

lactones such as γ-butyrolactone and γ-valerolactone;

carbonates such as diethyl carbonate and propylene carbonate; and the like.

Of these, in light of superior coating properties of the inorganic film-forming composition, the solvent (B) is preferably the alcohol solvent or the ester solvent. The alcohol solvent is preferably a monohydric aliphatic alcohol or an alkylene glycol monoalkyl ether, more preferably a monohydric aliphatic alcohol having 4 or more carbon atoms or an alkylene glycol monoalkyl ether having 4 or more carbon atoms, and still more preferably butanol, isoamyl alcohol, propylene glycol monomethyl ether, propylene glycol monoethyl ether or propylene glycol monopropyl ether. The ester solvent is preferably a hydroxyacid ester, a lactone, an alkylene glycol monoalkyl ether carboxylate or an ether group-containing alkylene glycol monoalkyl ether carboxylate, more preferably a hydroxyacid ester having 4 or more carbon atoms, a lactone having 4 or more carbon atoms, an ester of monocarboxylic acid with an alkylene glycol monoalkyl ether, an ester having 6 or more carbon atoms, and still more preferably ethyl lactate, γ-butyrolactone or propylene glycol monomethyl ether acetate.

The content of the solvent (B) is such a content that gives the content of the metal compound (A) in the inorganic film-forming composition of typically 0.1% by mass to 50% by mass, preferably 0.5% by mass to 30% by mass, more preferably 1% by mass to 15% by mass, and still more preferably 2% by mass to 10% by mass. When the content of the metal compound (A) in the inorganic film-forming composition falls within the above range, the storage stability and the coating properties of the composition can be more improved.

### (C) Crosslinking Accelerator

The inorganic film-forming composition may further contain the crosslinking accelerator (C). The crosslinking accelerator (C) generates an acid or a base by means of light or heat, and when the inorganic film-forming composition further contains the crosslinking accelerator (C), the resist pattern formability and the etching selectivity can be improved. The crosslinking accelerator (C) is exemplified by an onium salt compound, an N-sulfonyloxyimide compound, and the like. The crosslinking accelerator (C) is preferably a thermal crosslinking accelerator that thermally generates an acid or a base, and preferably an onium salt compound among thermal crosslinking accelerators.

The onium salt compound is exemplified by a sulfonium salt, a tetrahydrothiophenium salt, an iodonium salt, an ammonium salt, and the like.

Examples of the sulfonium salt include triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, 4-cyclohexylphenyldiphenylsulfonium trifluoromethanesulfonate, 4-cyclohexylphenyldiphenylsulfonium nonafluoro-n-butanesulfonate, 4-cyclohexylphenyldiphenylsulfonium perfluoro-n-octanesulfonate, 4-cyclohexylphenyldiphenylsulfonium 2-bicyclo[2.2.1]hept-2-yl-1, 1,2,2-tetrafluoroethanesulfonate, 4-methanesulfonylphenyldiphenylsulfonium trifluoromethanesulfonate, 4-methanesulfonylphenyldiphenylsulfonium nonafluoro-n-butanesulfonate, 4-methanesulfonylphenyldiphenylsulfonium perfluoro-n-octanesulfonate, 4-methanesulfonylphenyldiphenylsulfonium 2-bicyclo[2.2.1]hept-2-yl-1,1,2,2-tetrafluoroethanesulfonate, triphenylsulfonium 1,1,2,2-tetrafluoro-6-(1-adamantanecarbonyloxy)-hexane-1-sulfonate, and the like.

Examples of the tetrahydrothiophenium salt include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethanesulfonate, 1-(6-n-butoxynaphthalen-2-yl)tetrahydrothiophenium trifluoromethanesulfonate, 1-(6-n-butoxynaphthalen-2-yl)tetrahydrothiophenium nonafluoro-n-butanesulfonate, 1-(6-n-butoxynaphthalen-2-yl)tetrahydrothiophenium perfluoro-n-octanesulfonate, 1-(6-n-butoxynaphthalen-2-yl)tetrahydrothiophenium 2-bicyclo[2.2.1]hept-2-yl-1,1,2,2-tetrafluoroethanesulfonate, 1-(3,5-dimethyl-4-hydroxyphenyl)tetrahydrothiophenium trifluoromethanesulfonate, 1-(3,5-dimethyl-4-hydroxyphenyl)tetrahydrothiophenium nonafluoro-n-butanesulfonate, 1-(3,5-dimethyl-4-hydroxyphenyl)tetrahydrothiophenium perfluoro-n-octanesulfonate, 1-(3,5-dimethyl-4-hydroxyphenyl)tetrahydrothiophenium 2-bicyclo[2.2.1]hept-2-yl-1,1,2,2-tetrafluoroethanesulfonate, and the like.

Examples of the iodonium salt include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-bicyclo[2.2.1]hept-2-yl-1,1,2,2-tetrafluoroethanesulfonate, and the like.

Examples of the ammonium salt include ammonium formate, ammonium maleate, ammonium fumarate, ammonium phthalate, ammonium malonate, ammonium succinate, ammonium tartrate, ammonium malate, ammonium lactate, ammonium citrate, ammonium acetate, ammonium propionate, ammonium butanoate, ammonium pentanoate, ammonium hexanoate, ammonium heptanoate, ammonium octanoate, ammonium nonanoate, ammonium decanoate, ammonium oxalate, ammonium adipate, ammonium sebacate, ammonium butyrate, ammonium oleate, ammonium stearate, ammonium linoleate, ammonium linolenate, ammonium salicylate, ammonium benzenesulfonate, ammonium benzoate, ammonium p-aminobenzoate, ammonium p-toluenesulfonate, ammonium methanesulfonate, ammonium trifluoromethanesulfonate, ammonium tri fluoroethanesulfonate, and the like. In addition, ammonium salts derived by replacing the ammonium ion of the above-exemplified ammonium salt with a methylammonium ion, a dimethylammonium ion, a trimethylammonium ion, a tetramethylammonium ion, an ethylammonium ion, a diethylammonium ion, a triethylammonium ion, a tetraethylammonium ion, a propylammonium ion, a dipropylammonium ion, a tripropylammonium ion, a tetrapropylammonium ion, a butylammonium ion, a dibutylammonium ion, a tributylammonium ion, a tetrabutylammonium ion, a trimethylethylammonium ion, a dimethyldiethylammonium ion, a dimethylethylpropylammonium ion, a methylethylpropylbutylammonium ion, an ethanolammonium ion, a diethanolammonium ion, a triethanolammonium ion, or the like are also exemplified. Furthermore, 1,8-diazabicyclo[5.4.0]undec-7-ene salts such as a salt of 1,8-diazabicyclo[5.4.0]undec-7-ene with formic acid and a salt of 1,8-diazabicyclo[5.4.0]undec-7-ene with p-toluenesulfonic acid, 1,5-diazabicyclo[4.3.0]-5-nonene salts such as a salt of 1,5-diazabicyclo[4.3.0]-5-nonene with formic acid and a salt of 1,5-diazabicyclo[4.3.0]-5-nonene with p-toluenesulfonic acid, and the like are also exemplified.

Examples of the N-sulfonyloxyimide compound include N-(trifluoromethanesulfonyloxy)bicyclo[2.2.1]hept-5-ene-2,3-dicarboxyimide, N-(nonafluoro-n-butanesulfonyloxy)bicyclo[2.2.1]hept-5-ene-2,3-dicarboxyimide, N-(perfluoro-n-octanesulfonyloxy)bicyclo[2.2.1]hept-5-ene-2,3-dicarboxyimide, N-(2-bicyclo[2.2.1]hept-2-yl-1,1,2,2-tetrafluoroethanesulfonyloxy)bicyclo[2.2.1]hept-5-ene-2,3-dicarboxyimide, and the like.

Of these crosslinking accelerators (C), the onium salt compound is preferred, the iodonium salt and the ammonium salt are more preferred, and diphenyliodonium trifluoromethanesulfonate and tetramethylammonium acetate are still more preferred.

The crosslinking accelerator (C) may be used either alone, or two or more types thereof may be used in combination. The content of the crosslinking accelerator (C) with respect to 100 parts by mass of the metal compound (A) is preferably no less than 0 parts by mass and no greater than 10 parts by mass, and more preferably no less than 0.1 parts by mass and no greater than 5 parts by mass. When the content of the crosslinking accelerator (C) falls within the above range, the resist pattern formability and the etching selectivity of the inorganic film-forming composition can be more improved.

### Other Optional Component

The inorganic film-forming composition may contain other optional component such as a surfactant, within a range not leading to impairment of the effects of the present invention.

### Surfactant

The surfactant exhibits the effect of improving coating properties, striation and the like. Examples of the surfactant include: nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate and polyethylene glycol distearate; commercially available products such as KP341 (available from Shin-Etsu Chemical Co., Ltd.); Polyflow No. 75 and Polyflow No. 95 (each available from Kyoeisha Chemical Co., Ltd.); EFTOP EF301, EFTOP EF303 and EFTOP EF352 (each available from Tochem Products Co. Ltd.); Megaface F171 and Megaface F173 (each available from Dainippon Ink and Chemicals, Incorporated); Fluorad FC430 and Fluorad FC431 (each available from Sumitomo 3M Limited); ASAHI GUARD AG710, Surflon S-382, Surflon SC-101, Surflon SC-102, Surflon SC-103, Surflon SC-104, Surflon SC-105 and Surflon SC-106 (each available from Asahi Glass Co., Ltd.); and the like.

The surfactant may be used either alone, or two or more types thereof may be used in combination. Moreover, the amount of the surfactant blended may be appropriately selected in accordance with the purpose of the blending.

### Preparation Method of Composition for Forming Inorganic Film for Multilayer Resist Process

The inorganic film-forming composition may be prepared by, for example, mixing the metal compound (A) and the solvent (B), as well as the crosslinking accelerator (C), other optional component(s) and the like as needed, at a certain ratio. As described above, the solvent used in the synthesis of the metal compound (A) may be directly used as the solvent (B) to prepare the inorganic film-forming composition. The inorganic film-forming composition thus prepared is typically used after filtration thereof through a filter having a pore size of, for example, about 0.2 μm.

### Pattern-Forming Method

The pattern-forming method according to another embodiment of the present invention includes the steps of:

forming an inorganic film on the upper face side of a substrate (hereinafter, may be also referred to as “inorganic film formation step”);

forming a resist pattern on the upper face side of the inorganic film (hereinafter, may be also referred to as “resist pattern formation step”); and

dry-etching at least the inorganic film and the substrate, by each separate etching operation, using the resist pattern as a mask such that the substrate has a pattern (hereinafter, may be also referred to as “substrate pattern formation step”),

wherein the inorganic film is formed from the composition for forming an inorganic film for a multilayer resist process according to the embodiment of the present invention.

According to the pattern-forming method, since the inorganic film-forming composition described above is used, an inorganic film that is superior in resist pattern formability and etching selectivity can be formed while both superior removability with a cleaning solvent and superior volatilization inhibitory ability are exhibited. In addition, even when a thinner resist pattern is formed, dissipation, deformation, bending and the like of the resist pattern can be inhibited, thereby enabling a precise pattern transfer.

In the pattern-forming method,

the resist pattern formation step may include the steps of:

overlaying an antireflective film on the upper face side of the inorganic film; and

forming the resist pattern on the upper face side of the overlaid antireflective film.

In the pattern-forming method, in a case where the resist pattern is formed using a resist composition or the like on the upper face side of the inorganic film after the antireflective film is provided, the resist pattern formability can be more improved.

It is also preferred that the pattern-forming method further includes:

the step of forming a resist underlayer film on the substrate (hereinafter, may be also referred to as “resist underlayer film formation step”),

wherein in the inorganic film formation step, the inorganic film is formed on the upper face side of the resist underlayer film.

Since the inorganic film-forming composition is superior in etching selectivity with respect to organic materials, the resist pattern can be transferred by sequentially dry-etching the inorganic film, and the resist underlayer film which is an organic film. Hereinafter, each step will be described.

### Inorganic Film Formation Step

In this step, an inorganic film is formed on the upper face side of a substrate using the inorganic film-forming composition. Examples of the substrate include insulating films such as silicon oxide, silicon nitride, silicon nitride oxide and polysiloxane, as well as interlayer insulating films such as wafers covered with a low-dielectric insulating film such as Black Diamond™ (available from AMAT), SiLK™ (available from Dow Chemical), LKDS109 (available from JSR Corporation), which are commercially available products, and the like. Moreover, a substrate patterned so as to have wiring grooves (trenches), plug grooves (vias) or the like may be used as the substrate. The inorganic film may be formed by applying the inorganic film-forming composition on the surface of the substrate to provide a coating film, subjecting the coating film to a heat treatment, or a combination of irradiation with ultraviolet light and a heat treatment to permit hardening, baking, and/or the like. The procedure for applying the inorganic film-forming composition is exemplified by a spin-coating procedure, a roll-coating procedure, a dip coating procedure, and the like. Moreover, the temperature in the heat treatment is typically 150° C. to 500° C., and preferably 180° C. to 350° C. The time period of the heat treatment is typically 30 sec to 1,200 sec, and preferably 45 sec to 600 sec. The condition of the irradiation with ultraviolet light may be appropriately selected in accordance with the formulation of the inorganic film-forming composition, and the like. The film thickness of the formed inorganic film is typically about 5 nm to about 50 nm.

### Resist Underlayer Film Formation Step

Alternatively, the step of forming on the substrate a resist underlayer film which is an organic film using a composition for forming a resist underlayer film may be included before the inorganic film formation step. Conventionally well-known compositions for forming a resist underlayer film may be used as the composition for forming a resist underlayer film, and examples thereof include NFC HM8005 (available from JSR Corporation), and the like. The resist underlayer film may be formed by applying the composition for forming a resist underlayer film on the substrate to provide a coating film, and subjecting the coating film to a heat treatment, or a combination of irradiation with ultraviolet light and a heat treatment to permit hardening, drying, and/or the like. The procedure for applying the composition for forming a resist underlayer film is exemplified by a spin-coating procedure, a roll-coating procedure, a dip coating procedure, and the like. Moreover, the temperature in the heat treatment is typically 150° C. to 500° C., and preferably 180° C. to 350° C. The time period of the heat treatment is typically 30 sec to 1,200 sec, and preferably 45 sec to 600 sec. The condition of the irradiation with ultraviolet light may be appropriately selected in accordance with the formulation of the composition for forming a resist underlayer film, and the like. The film thickness of the formed resist underlayer film is typically about 50 nm to about 500 nm.

In addition, other underlayer film distinct from the resist underlayer film may be formed on the surface of the substrate. This other underlayer film is a film to which an antireflecting function, coating film flatness, superior etching resistance against fluorine-containing gases such as CF₄ and/or the like are/is imparted.

### Resist Pattern Formation Step

In this step, a resist pattern is formed on the upper face side of the formed inorganic film. The procedure for forming the resist pattern is exemplified by: (A) a procedure involving the use of a resist composition; (B) a procedure involving nanoimprint lithography; and the like. Hereinafter, each procedure will be described.

(A) Procedure Involving Use of Resist Composition

In a case where this procedure is employed, the resist pattern formation step includes the steps of:

forming a resist film on the upper face side of the inorganic film using the resist composition (hereinafter, may be also referred to as “resist film formation step”);

exposing the resist film (hereinafter, may be also referred to as “exposure step”); and

developing the resist film exposed (hereinafter, may be also referred to as “development step”).

Hereinafter, each step will be described.

Resist Film Formation Step

In this step, a resist film is formed on the upper face side of the inorganic film using the resist composition. The resist composition is exemplified by: a resist composition that contains a polymer having an acid-labile group, and a radiation-sensitive acid generating agent; a positive resist composition that contains an alkali-soluble resin and a quinone diazide photosensitizing agent; a negative resist that contains an alkali-soluble resin and a crosslinking agent; and the like. Commercially available resist compositions may be used as the resist composition. The resist composition may be applied by, for example, a conventional procedure such as a spin-coating procedure. It is to be noted that in applying the resist composition, the amount of the resist composition applied is adjusted such that the resulting resist film has a desired film thickness. The resist film may be formed on the upper face side of an antireflective film after overlaying the antireflective film on the upper face side of the inorganic film. When the resist pattern is thus formed using the resist composition accompanied by the formation of the antireflective film, the formability of the resulting resist pattern can be more improved.

The resist film can be formed by subjecting the coating film provided through the application of the resist composition to prebaking (PB), etc., and thereby evaporating the solvent in the coating film to dryness. The temperature in the PB may be appropriately adjusted in accordance with the type of the resist composition employed, and the like; the temperature in the PB is preferably 30° C. to 200° C., and more preferably 50° C. to 150° C. The time period of the PB is typically 30 sec to 200 sec, and preferably 45 sec to 120 sec. The film thickness of the formed resist film is typically 1 nm to 500 nm, and preferably 10 nm to 300 nm. It is to be noted that other film may be further provided on the surface of the resist film.

Exposure Step

In this step, the formed resist film is exposed. This exposure is typically carried out by selectively irradiating the resist film with a radioactive ray through a photomask. The radioactive ray which may be employed in the exposure may be appropriately selected in accordance with the type of the acid generating agent contained in the resist composition, from e.g., electromagnetic waves such as visible light rays, ultraviolet rays, far ultraviolet rays, X-rays and γ radiations; particle beams (or particle rays) such as electron beams, molecular beams and ion beams; and the like. Of these, far ultraviolet rays are preferred, and a KrF excimer laser beam (248 nm), an ArF excimer laser beam (193 nm), an F₂ excimer laser beam (wavelength: 157 nm), a Kr₂ excimer laser beam (wavelength: 147 nm), an ArKr excimer laser beam (wavelength: 134 nm), and extreme-ultraviolet rays (wavelength: 13 nm, etc.) are more preferred. The exposure may also be carried out through a liquid immersion medium. In such an exposure, a liquid immersion upper layer film may be provided on the upper face side of the resist film using a composition for forming a liquid immersion upper layer film.

In order to improve the resolution, the pattern profile, the developability, etc. of the resist film, post-baking is preferably carried out after the exposure. The temperature in the post-baking may be appropriately adjusted in accordance with the type of the resist composition employed and the like; the temperature in the post-baking is preferably 50° C. to 180° C., and more preferably 70° C. to 150° C. The time period of the post-baking is typically 30 sec to 200 sec, and preferably 45 sec to 120 sec.

Development Step

In this step, the resist film exposed is developed. The developer solution used in the development may be appropriately selected in accordance with the type of the resist composition employed. In the case where: the resist composition that contains a polymer having an acid-labile group, and a radiation-sensitive acid generating agent; or a positive resist composition that contains an alkali-soluble resin is used, an alkaline aqueous solution of e.g., sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide (TMAH), tetraethylammonium hydroxide, pyrrole, piperidine, choline, 1,8-diazabicyclo[5.4.0]-7-undecene, 1,5-diazabicyclo[4.3.0]-5-nonene or the like may be employed, and thereby a positive resist pattern can be formed. Of these, an aqueous TMAH solution is preferred. An appropriate amount of a water soluble organic solvent, e.g., an alcohol such as methanol and ethanol, and/or a surfactant may be added to the alkaline aqueous solution.

Moreover, in the case of the resist composition that contains a polymer having an acid-labile group, and a radiation-sensitive acid generating agent, a liquid containing an organic solvent may be used as the developer solution, and thereby a negative resist pattern can be formed. Thus, by using the resist composition that contains a polymer having an acid-labile group, and the developer solution containing an organic solvent, a finer resist pattern can be formed, and, in turn, a finer substrate pattern can be formed. Examples of the organic solvent include solvents similar to those exemplified in connection with the solvent (B) of the inorganic film-forming composition, and the like. Of these, ester solvents are preferred, and butyl acetate is more preferred.

Alternatively, in the case of the negative chemically amplified resist composition, or the negative resist that contains an alkali-soluble resin, an aqueous solution of an alkali, e.g.: an inorganic alkali such as sodium hydroxide, potassium hydroxide, sodium carbonate, sodium silicate, sodium metasilicate or aqueous ammonia; a primary amine such as ethylamine or n-propylamine; a secondary amine such as diethylamine or di-n-butylamine; a tertiary amine such as triethylamine or methyldiethylamine; an alcoholamine such as dimethylethanolamine or triethanolamine; a quaternary ammonium salt such as tetramethylammonium hydroxide, tetraethylammonium hydroxide or choline; a cyclic amine such as pyrrole or piperidine, or the like may be employed.

(B) Procedure Involving Nanoimprint Lithography

In a case where this procedure is employed, the resist pattern formation step includes the step of:

forming a resist pattern on the upper face side of the inorganic film by nanoimprint lithography using the resist composition (hereinafter, may be also referred to as “resist pattern formation step by nanoimprint lithography”).

This step will be described below.

Resist Pattern Formation Step by Nanoimprint Lithography

In this step, a resist pattern is formed on the upper face side of the inorganic film by nanoimprint lithography using the resist composition. More specifically regarding this step, this step includes the steps of forming a pattern formation layer on the upper face side of the inorganic film (hereinafter, may be also referred to as “pattern formation layer formation step”); subjecting the surface of a mold having a reversal pattern on the surface thereof to a hydrophobilization treatment (hereinafter, may be also referred to as “hydrophobilization treatment step”); pressing the hydrophobized surface of the mold on the pattern formation layer (hereinafter, may be also referred to as “pressing step”); exposing the pattern formation layer while the mold is pressed (hereinafter, may be also referred to as “exposure step”); and releasing the mold from the pattern formation layer exposed (hereinafter, may be also referred to as “releasing step”).

Each step will be described below.

Pattern Formation Layer Formation Step

In this step, a pattern formation layer is formed on the upper face side of the inorganic film. A material constituting the pattern formation layer is a radiation-sensitive composition for nanoimprinting. The pattern formation layer may contain, in addition to the radiation-sensitive composition for nanoimprinting, a hardening accelerator, and the like. The hardening accelerator is exemplified by a radiation-sensitive hardening accelerator and a thermal hardening accelerator. Of these, the radiation-sensitive hardening accelerator is preferred. The radiation-sensitive hardening accelerator may be appropriately selected in accordance with constituents unit constituting the radiation-sensitive composition for nanoimprinting, and examples thereof include photoacid generating agents, photobase generating agents, photosensitizing agents, and the like. It is to be noted that the radiation-sensitive hardening accelerator may be used either alone, or two or more types thereof may be used in combination.

Examples of the procedure for applying the radiation-sensitive composition include an ink jet procedure, a dip coating procedure, an air knife coating procedure, a curtain coating procedure, a wire bar coating procedure, a gravure coating procedure, an extrusion coating procedure, a spin coating procedure, a slit scan procedure, and the like.

Hydrophobilization Treatment Step

In this step, the surface of a mold having a reversal pattern on the surface thereof is subjected to a hydrophobilization treatment. The mold needs to be made from an optically transparent material. Examples of the optically transparent material include: glass; quartz; optically transparent resins such as PMMA and polycarbonate resins; transparent metal vapor-deposited films; flexible films of a polydimethylsiloxane or the like; photo-cured films; metal films; and the like.

For example, a release agent or the like is used in the hydrophobilization treatment. Examples of the release agent include silicon-containing release agents, fluorine-containing release agents, polyethylene-containing release agents, polypropylene-containing release agents, paraffin-containing release agents, montan-containing release agents, carnauba-containing release agents, and the like. It is to be noted that the release agent may be used either alone, or two or more types thereof may be used in combination. Of these, the silicon-containing release agents are preferred. Examples of the silicon-containing release agents include polydimethylsiloxanes, acryl silicone graft polymers, acrylsiloxanes, arylsiloxanes, and the like.

Pressing Step

In this step, the hydrophobized surface of the mold is pressed on the pattern formation layer. By pressing the mold having a relief pattern on the pattern formation layer, the relief pattern of the mold is transferred to the pattern formation layer. The pressure in pressing the mold is typically 0.1 MPa to 100 MPa, preferably 0.1 MPa to 50 MPa, and more preferably 0.1 MPa to 30 MPa. The time period of the pressing is typically 1 sec to 600 sec, preferably 1 sec to 300 sec, and more preferably 1 sec to 180 sec.

Exposure Step

In this step, the pattern formation layer is exposed while the mold is pressed. Upon the exposure of the pattern formation layer, a radical species is generated from a photopolymerization initiator contained in the radiation-sensitive composition for nanoimprinting. Thus, the pattern formation layer constituted with the radiation-sensitive composition for nanoimprinting is hardened while the relief pattern of the mold is transferred thereto. After the transfer of the relief pattern, the resulting film can be used as: a film for interlayer insulating films in semiconductor devices such as, e.g., LSI, system LSI, DRAM, SDRAM, RDRAM, D-RDRAM; a resist film for use in the production of semiconductor devices; and the like.

Alternatively, in a case where the pattern formation layer has a thermosetting property, heat hardening may be further carried out. When the heat hardening is carried out, the heating atmosphere, the heating temperature and the like are not particularly limited; for example, the heating may be carried out at 40° C. to 200° C. under an inert atmosphere or under a reduced pressure. The heating may be carried out using a hot plate, an oven, a furnace, or the like.

Releasing Step

In this step, the mold is released from the pattern formation layer exposed. The releasing procedure is not particularly limited; for example, the releasing may be achieved by moving the mold away from a base with the base fixed, or by moving the base away from the mold with the mold fixed. Alternatively, the releasing may be achieved by pulling the base and the mold in the opposite direction.

### Substrate Pattern Formation Step

In this step, at least the inorganic film and the substrate are dry-etched by each separate etching operation using the resist pattern as a mask such that the substrate has a pattern. It is to be noted that in a case where the resist underlayer film is provided, the inorganic film, the resist underlayer film and the substrate are sequentially dry-etched using the resist pattern as a mask, whereby a pattern formed. The dry-etching may be carried out using a well-known dry-etching apparatus. In addition, examples of the gas which may be used as a source gas in the dry-etching include: oxygen atom-containing gases such as O₂, CO and CO₂; inert gases such as He, N₂ and Ar; chlorine-containing gases such as Cl₂ and BCl₃; fluorine-containing gases such as CHF₃ and CF₄; other gases such as H₂ and NH₃, which may be selected in accordance with the elemental composition of the substrate to be etched. It is to be noted that these gases may also be used as a mixture.

### EXAMPLES

Hereinafter, the embodiments of the present invention will be described in more detail by way of Examples, but the present invention is not in any way limited to these Examples. Measuring methods for physical properties in Examples are shown below.

### Absolute Molecular Weight of Metal Compound

The absolute molecular weight of the metal compound was determined by static light scattering using the following apparatus under the following conditions:

apparatus: light scattering measurement apparatus (“ALV-5000” available from ALV-GmbH, Germany);

condition: each solution having a concentration of 2.5% by mass, 5.0% by mass, 7.5% by mass, or 10.0% by mass was prepared, and the solution after filtration was charged into a quartz cell, followed by the determination on the apparatus;

standard liquid: toluene; and

measurement temperature: 23° C.

It is to be noted that the following parameters which were necessary for the calculation of the absolute molecular weight were determined using the following apparatuses:

refractive index of solution: refractometer (“RA-500” available from Kyoto Electronics Manufacturing Co., Ltd.); and

density of solution: density/specific gravity meter (“DA-100” available from Kyoto Electronics Manufacturing Co., Ltd.).

### Solid Content Concentration

On an aluminum dish which had been weighed to confirm the mass (A (g)) was placed 1.00 g of a solution as a test sample for the solid content concentration, and the aluminum dish was heated on a hot plate at 150° C. for 1 hour in an ambient air. Thereafter the aluminum dish was cooled to room temperature, and then the mass (B (g)) of the aluminum dish (including the residues) was measured. The solid content concentration of the solution was calculated using the values of the mass, A and B, according to the following equation:

solid content concentration (% by mass)=(B−A)×100.

### Synthesis of Metal Compound (A)

Compounds used in the synthesis of the metal compound (A) are shown below.

M-1: titanium(IV) diisopropoxy bis(2,4-pentanedionato) (a 2-propanol solution having a concentration of 75% by mass)

M-2: titanium(IV) diisopropoxy bis(ethyl acetoacetato)

M-3: zirconium(IV) di-n-butoxide bis(2,4-pentanedionato) (a butanol solution having a concentration of 60% by mass)

M-4: tantalum(V) tetraethoxy (2,4-pentanedionato)

M-5: bis(cyclopentadienyl)tungsten(IV) dichloride

### Synthesis Example 1

The compound (M-1) in an amount of 50.9 g (the mass of the metal compound: 38.2 g, 0.105 mol) was dissolved in 178.9 g of propylene glycol monoethyl ether. After thorough stirring, 20.2 g (1.12 mol) of water was added to this solution dropwise at room temperature over 10 min. Thereafter, the reaction was allowed to proceed at 60° C. for 2 hrs, and then the reaction mixture was cooled at room temperature. Then, 250 g of propylene glycol monoethyl ether was further added to the reaction mixture, and then vacuum concentration was carried out using a rotary evaporator to obtain a solution free from components having a low boiling point. This solution had a solid content concentration of 11.0% by mass. Moreover, the absolute molecular weight of the metal compound (A) contained in this solution as determined by static light scattering was 24,500. This solution was diluted with propylene glycol monoethyl ether to prepare a solution (S-1) of the metal compound (A), the solution (S-1) having a solid content concentration of 3% by mass.

### Comparative Synthesis Example 1

The compound (M-1) in an amount of 40.00 g (the mass of the metal compound: 30.0 g, 0.082 mol) and 54.1 g of propylene glycol monomethyl ether were mixed, and after thorough stirring at room temperature, 5.94 g (0.33 mol) of water was mixed therewith. The temperature of the mixture was elevated to 60° C., and stirring was carried out for 4 hrs with heating. After the completion of the reaction, the reaction mixture was cooled to room temperature. Then, 50.0 g of propylene glycol monomethyl ether was added to the reaction mixture, and then vacuum concentration was carried out using a rotary evaporator to obtain a solution free from components having a low boiling point. This solution had a solid content concentration of 11.0% by mass. Moreover, the absolute molecular weight of the metal compound contained in this solution as determined by static light scattering was 6,000. This solution was diluted with propylene glycol monomethyl ether to prepare a solution (CS-1) of the metal compound, the solution (CS-1) having a solid content concentration of 3% by mass.

### Synthesis Example 2

The compound (M-2) in an amount of 7.6 g (0.018 mol) was dissolved in 40.2 g of 2-propanol. After thorough stirring, a mixed solution of 0.54 g (0.030 mol) of water and 0.17 g (1.7 mmol) of maleic anhydride was added to this solution dropwise at room temperature over 10 min. Thereafter, the reaction was allowed to proceed at 60° C. for 4 hrs, and then the reaction mixture was cooled at room temperature. Then, 50 g of propylene glycol monomethyl ether acetate was further added to the reaction mixture, and then vacuum concentration was carried out using a rotary evaporator to obtain a solution free from components having a low boiling point. This solution had a solid content concentration of 10.5% by mass. Moreover, the absolute molecular weight of the metal compound (A) contained in this solution as determined by static light scattering was 8,600. This solution was diluted with propylene glycol monomethyl ether acetate to prepare a solution (S-2) of the metal compound (A), the solution (S-2) having a solid content concentration of 3% by mass.

### Comparative Synthesis Example 2

The compound (M-2) in an amount of 7.6 g (0.018 mol) was dissolved in 40.2 g of 2-propanol. After thorough stirring, a mixed solution of 1.08 g (0.060 mol) of water and 0.17 g (1.7 mmol) of maleic anhydride was added to this solution dropwise at room temperature over 10 min. Thereafter, the reaction was allowed to proceed at 60° C. for 4 hrs, and then the reaction mixture was cooled at room temperature. Then, 50 g of propylene glycol monomethyl ether acetate was further added to the reaction mixture, and then vacuum concentration was carried out using a rotary evaporator to obtain a solution free from components having a low boiling point. This solution had a solid content concentration of 10.8% by mass. Moreover, the absolute molecular weight of the metal compound contained in this solution as determined by static light scattering was 86,700. This solution was diluted with propylene glycol monomethyl ether acetate to prepare a solution (CS-2) of the metal compound, the solution (CS-2) having a solid content concentration of 3% by mass.

### Synthesis Example 3

The compound (M-3) in an amount of 16.7 g (the mass of the metal compound: 10.0 g, 0.023 mol) was dissolved in 99.6 g of 1-butanol. After thorough stirring, 2.5 g (0.14 mol) of water was added to this solution dropwise at room temperature over 10 min. Thereafter, the reaction was allowed to proceed at 70° C. for 3 hrs, and then the reaction mixture was cooled at room temperature. Then, 100 g of 1-butanol was further added to the reaction mixture, and then vacuum concentration was carried out using a rotary evaporator to obtain a solution free from components having a low boiling point. This solution had a solid content concentration of 11.3% by mass. Moreover, the absolute molecular weight of the metal compound (A) contained in this solution as determined by static light scattering was 45,000. This solution was diluted with 1-butanol to prepare a solution (S-3) of the metal compound (A), the solution (S-3) having a solid content concentration of 3% by mass.

### Comparative Synthesis Example 3

The compound (M-3) in an amount of 16.7 g (the mass of the metal compound: 10.0 g, 0.023 mol) was dissolved in 99.6 g of propylene glycol monopropyl ether. Next, 0.41 g (0.023 mol) of water was added to this solution, and the mixture was stirred at room temperature for 24 hrs. An aliquot (11.7 g) of the obtained solution (the aliquot containing 0.0023 mol of Zr) was taken out, and mixed with 0.25 g (1.15 mmol) of 2-cyano-3-(4-hydroxyphenyl)acrylic acid ethyl ester (CHAE). The mixture was stirred at room temperature for 1 hour to obtain a solution. This solution had a solid content concentration of 8.0% by mass. Moreover, the absolute molecular weight of the metal compound contained in this solution as determined by static light scattering was 2,500. This solution was diluted with propylene glycol monopropyl ether to prepare a solution (CS-3) of the metal compound, the solution (CS-3) having a solid content concentration of 3% by mass.

### Synthesis Example 4

The compound (M-4) in an amount of 4.6 g (0.010 mol) was dissolved in 44.32 g of ethanol. After thorough stirring, 1.08 g (0.060 mol) of water was added to this solution dropwise at room temperature over 10 min. Thereafter, the reaction was allowed to proceed at 60° C. for 1 hour, and then the reaction mixture was cooled at room temperature. Then, 50 g of γ-butyrolactone was further added to the reaction mixture, and then vacuum concentration was carried out using a rotary evaporator to obtain a solution free from components having a low boiling point. This solution had a solid content concentration of 11.0% by mass. Moreover, the absolute molecular weight of the metal compound (A) contained in this solution as determined by static light scattering was 29,000. This solution was diluted with γ-butyrolactone to prepare a solution (S-4) of the metal compound (A), the solution (S-4) having a solid content concentration of 3% by mass.

### Synthesis Example 5

The compound (M-5) in an amount of 3.8 g (0.010 mol) was dissolved in 44.42 g of ethyl lactate. After thorough stirring, 1.8 g (0.10 mol) of water was added to this solution dropwise at room temperature over 10 min. Thereafter, the reaction was allowed to proceed at 60° C. for 2 hrs, and then the reaction mixture was cooled at room temperature. Then, 50 g of ethyl lactate was further added to the reaction mixture, and then vacuum concentration was carried out using a rotary evaporator to obtain a solution free from components having a low boiling point. This solution had a solid content concentration of 11.0% by mass. Moreover, the absolute molecular weight of the metal compound (A) contained in this solution as determined by static light scattering was 13,000. This solution was diluted with ethyl lactate to prepare a solution (S-5) of the metal compound (A), the solution (S-5) having a solid content concentration of 3% by mass.

### Preparation of Composition for Forming Inorganic Film for Multilayer Resist Process

The crosslinking accelerators (C) used in the preparation of the inorganic film-forming composition are shown below.

(C) Crosslinking Accelerator

C-1: diphenyliodonium trifluoromethanesulfonate

C-2: tetramethylammonium acetate

### Example 1

The solution (S-1) of the metal compound obtained as described above in an amount of 100.0 parts by mass was filtered through a filter having a pore size of 0.2 μm, whereby a composition for forming an inorganic film for a multilayer resist process (J-1) was prepared.

### Examples 2 to 5 and Comparative Examples 1 to 3

Compositions for forming an inorganic film for a multilayer resist process (J-2) to (J-5) and (CJ-1) to (CJ-3) were prepared by a similar operation to that of Example 1 except that solutions of the metal compounds of the type shown in Table 1 below in an amount of 100.0 parts by mass were used, and that the type and the amount of the crosslinking accelerator (C) used as needed were as shown in Table 1. It is to be noted that “-” indicates that the corresponding component was not used.

### Evaluations

The compositions for forming an inorganic film for a multilayer resist process prepared as described above were evaluated according to the following methods. The results of the evaluations are shown together in Table 1.

Removability with Cleaning Solvent

The composition for forming an inorganic film for a multilayer resist process was dropped on a silicon wafer as a substrate, and thereafter the substrate was rotated at 1,000 rpm for 30 sec, whereby a coating film (unheated film) was provided. A part of this coating film (an inorganic film remaining after the application and drying by the rotation) was immersed for 1 min in γ-butyrolactone as a cleaning solvent for cleaning the edge and the back face of the substrate, and then was dried using an air spray gun. The removability with a cleaning solvent was evaluated based on the degree of removal of the unheated film in this process according to the following criteria:

A (favorable): complete removal of the film being identified by visual inspection; and

B (unfavorable): failure of removal at a part of the film being identified by visual inspection.

### Volatilization Inhibitory Ability

The composition for forming an inorganic film for a multilayer resist process was applied on an 8-inch silicon wafer as a substrate using a spin-coater to provide a coating film. Other 8-inch silicon wafer as a blank substrate was placed just above the coating film on the substrate such that the front face of the other 8-inch silicon wafer faces the coating film, with a 0.75 mm spacer being interposed therebetween. Thereafter, the coated substrate paired with the blank wafer was heated at 250° C. for 5 min, and a component volatilized from the coating film was trapped by the blank wafer. Next, a center portion of the blank wafer used in the trapping was cut into a 1 cm square piece, then the front face of the cut piece was etched with 0.1 mL of a 12.5% by mass aqueous hydrofluoric acid solution, and the obtained liquid was diluted 10-fold with ultra pure water. The amount of the metal contained in the diluted liquid was measured using an ICP-MS measurement apparatus (“Agilent 7500s” available from Agilent Technologies), whereby quantitative determination of the inorganic film-derived component volatilized during the baking was made. This sequence of operations was repeated three times. In addition, as a reference test, the same sequence of operations as the above sequence was repeated three times on a fresh blank wafer which was not subjected to the aforementioned trapping operation. In regard to the relationship between two averages (S) and (R), i.e., the average (S) of the values obtained in three analyses of the inorganic film-derived component contained in the liquid recovered after the etching of the blank wafer used in the trapping and the average (R) of the values obtained in three analyses of the inorganic film-derived component contained in the liquid recovered after the etching in the reference test, in a case where S/R was less than 1.1, the volatilization inhibitory ability was evaluated to be “A (favorable)”, whereas in a case where S/R was no less than 1.1, the volatilization inhibitory ability was evaluated to be “B (unfavorable)”.

### Resist Pattern Formability

Resist Composition: Development with Aqueous Alkali Solution

A composition for forming a resist underlayer film (“NEC HM8005” available from JSR Corporation) was applied on a silicon wafer as a substrate using a spin-coater, followed by drying on a hot plate at 250° C. for 60 sec, whereby a resist underlayer film having a film thickness of 300 nm was formed. A composition for forming an inorganic film for a multilayer resist process was applied on the formed resist underlayer film using a spin-coater, followed by baking on a hot plate at 250° C. for 60 sec, whereby an inorganic film having a film thickness of 20 nm was formed. A resist composition (“ARX2014J” available from JSR Corporation) was applied on the formed inorganic film, followed by drying at 90° C. for 60 sec, whereby a resist film having a film thickness of 100 nm was formed. A composition for forming a liquid immersion upper layer film (“NFC TCX091-7” available from JSR Corporation) was applied the formed resist film, followed by drying at 90° C. for 60 sec, whereby a liquid immersion upper layer film having a film thickness of 30 nm was formed. Next, an exposure was carried out according to a liquid immersion exposure process at an exposure dose of 16 mJ/cm² through a photomask for forming a line-and-space pattern in which both lines and spaces had a width of 50 nm, using an ArF excimer laser irradiation apparatus (“S610C” available from NIKON Corporation), and thereafter, the substrate including the resist film was heated at 115° C. for 60 sec. Then, a development was carried out for 30 sec using a 238% by mass aqueous tetramethylammonium hydroxide solution as a developer solution, whereby a 50 nm 1L/1S resist pattern was formed. The resist pattern thus formed was observed using a scanning electron microscope (available from Hitachi High-Technologies Corporation), and in the 50 nm line-and-space pattern, the resist pattern formability was evaluated to be: “A (favorable)” in a case where the resist pattern did not spread toward the bottom; and “B (unfavorable)” in a case where the resist pattern spread toward the bottom. A pattern transfer was carried out by sequentially dry-etching the inorganic film and the substrate using the formed resist pattern as a mask, and a dry-etching apparatus (“Telius SCCM” available from Tokyo Electron Limited).

Resist Composition: Development with Organic Solvent

A composition for forming a resist underlayer film (“NFC HM8005” available from JSR Corporation) applied on a silicon wafer as a substrate using a spin-coater, followed by drying on a hot plate at 250° C. for 60 sec, whereby a resist underlayer film having a film thickness of 300 nm was formed. A composition for forming an inorganic film for a multilayer resist process was applied on the formed resist underlayer film using a spin-coater, followed by baking on a hot plate at 250° C. for 60 sec, whereby an inorganic film having a film thickness of 20 nm was formed. A resist composition (“ARX2014J” available from JSR Corporation) was applied on the formed inorganic film, followed by drying at 90° C. for 60 sec, whereby a resist film having a film thickness of 100 nm was formed. A composition for forming a liquid immersion upper layer film (“NFC TCX091-7” available from JSR Corporation) was applied on the formed resist film, followed by drying at 90° C. for 60 sec, whereby a liquid immersion upper layer film having a film thickness of 30 nm was formed. Next, an exposure was carried out according to a liquid immersion exposure process at an exposure dose of 16 mJ/cm² through a photomask for forming a line-and-space pattern in which both lines and spaces had a width of 40 nm, using an ArF excimer laser irradiation apparatus (“S610C” available from NIKON Corporation), and thereafter the substrate including the resist film was heated at 115° C. for 60 sec. Then, a puddle development was carried out for 30 sec using butyl acetate as a developer solution, followed by rinsing with methylisobutylcarbinol (MIBC). After spin-drying at 2,000 rpm for 15 sec, a 40 nm 1L/1S resist pattern was formed. The formed resist pattern was observed using a scanning electron microscope (available from Hitachi High-Technologies Corporation). In the 40 nm line-and-space pattern, the resist pattern formability was evaluated to be: “A (favorable)” in a case where the resist pattern did not spread toward the bottom; and “B (unfavorable)” in a case where the resist pattern spread toward the bottom. A pattern transfer was carried out by sequentially dry-etching the inorganic film and the substrate using the formed resist pattern as a mask, and a dry-etching apparatus (“Telius SCCM” available from Tokyo Electron Limited).

### Etching Selectivity

The inorganic film was etched according to the following two methods using the aforementioned etching apparatus, and etching selectivity was evaluated.

(1) under a condition in which the aforementioned resist underlayer film (NFC HM8005) was etched at a rate of 200 nm per min; and

(2) under a condition in which the silicon dioxide film was etched at a rate of 100 nm.

Under each etching condition, the etching selectivity was evaluated to be: “A (favorable)” in a case where the difference between the initial film thickness of the inorganic film and the film thickness of the inorganic film after the etching was less than 5 nm; and “B (unfavorable)” in a case where the difference was no less than 5 nm. In regard to the inorganic film-forming composition whose etching selectivity was evaluated to be favorable, the inorganic film formed from such inorganic film-forming composition can favorably serve as a mask film in the processing of each film (i.e., the resist underlayer film or the silicon dioxide film).

TABLE 1

| | | Component | | | | | | | | | |
|---|---|---|---|---|---|---|---|---|---|---|---|
| | Composition | solution of metal | | (C) crosslinking | | Evaluation results | | | | | |
| | for forming | compound (A) | | accelerator | | removability | | resist pattern formability | | etching selectivity | |
| | inorganic film | | amount | | amount | with | volatilization | | development | resist | silicon |
| | for multilayer | | (parts by | | (parts by | cleaning | inhibitory | development | with organic | underlayer | dioxide |
| | resist process | type | mass) | type | mass) | solvent | ability | with alkali | solvent | film | film |
| Example 1 | J-1 | S-1 | 100 | — | — | A | A | A | A | A | A |
| Example 2 | J-2 | S-2 | 100 | C-1 | 0.025 | A | A | A | A | A | A |
| Example 3 | J-3 | S-3 | 100 | — | — | A | A | A | A | A | A |
| Example 4 | J-4 | S-4 | 100 | C-2 | 0.05 | A | A | A | A | A | A |
| Example 5 | J-5 | S-5 | 100 | — | — | A | A | A | A | A | B |
| Comparative | CJ-1 | CS-1 | 100 | — | — | A | B | A | A | A | A |
| Example 1 | | | | | | | | | | | |
| Comparative | CJ-2 | CS-2 | 100 | C-1 | 0.025 | B | A | A | A | A | A |
| Example 2 | | | | | | | | | | | |
| Comparative | CJ-3 | CS-3 | 100 | — | — | A | B | A | A | A | A |
| Example 3 | | | | | | | | | | | |

As is clear from the results shown in Table 1, it is seen that in the compositions for forming an inorganic film for a multilayer resist process according to Examples, the inorganic film left yet after the application and spin-drying of the compositions exhibited favorable solubility in a solvent for cleaning the edge and the back face of the substrate, and also exhibited inhibition of the volatilization of the inorganic component during the baking. Furthermore, it is seen that the formed inorganic films were superior in etching selectivity, and also superior in resist pattern formability. In Example 5, the etching resistance under the condition for etching a silicon dioxide film was evaluated to be unfavorable. This is inferred to be attributed to the ease of etching of the tungsten oxide film, which was obtained after the baking, under the condition for etching the silicon dioxide film. Therefore, the inorganic film obtained in Example 5 is considered to be effective only as a mask in etching processing of the resist underlayer film.

On the other hand, in regard to the compositions for forming an inorganic film according to Comparative Examples, the volatilization inhibitory ability of the inorganic films obtained in Comparative Examples 1 and 3 was evaluated to be unfavorable. This is inferred to be attributed to low absolute molecular weight of the metal compounds, and, in turn, the presence of a large quantity of a component that is readily volatilized by heating even after the application and spin-drying of the composition. In Comparative Example 2, it is inferred that the removability with a cleaning solvent of the inorganic film obtained after the application and spin-drying of the composition is unfavorable due to too high absolute molecular weight of the metal compound.

The embodiments of the present invention can provide: a composition for forming an inorganic film for a multilayer resist process, the composition exhibiting favorable solubility in a solvent for cleaning the end and the back face of a substrate after the application and spin-drying of the composition, less volatilization of an inorganic substance during baking of the film formed therefrom, and also superior resist pattern formability and etching selectivity, as well as a pattern-forming method using the composition. Therefore, in a multilayer resist process employing the composition for forming an inorganic film, an inorganic film formed after the application and spin-drying of the composition exhibits a superior performance in removing the thus formed film with an organic solvent at a site on the substrate where the removal of the film is desired, a chamber is less likely to be contaminated with an inorganic substance during the baking, and even when a thinner organic film is formed, dissipation, deformation, bending and the like of the resist pattern can be inhibited, leading to a precise pattern transfer. Therefore, the embodiments of the present invention can be highly suitably used in production processes of LSIs in which further progress of miniaturization is expected in the future, in particular, for forming finer contact holes and the like.

Obviously, numerous modifications and variations of the present invention are possible in light of the above teachings. It is therefore to be understood that within the scope of the appended claims, the invention may be practiced otherwise than as specifically described herein.

1. A composition, comprising:
a metal compound comprising:
a plurality of metal atoms of titanium, tantalum, zirconium, tungsten or a combination thereof;
oxygen atoms each crosslinking the metal atoms; and
polydentate ligands each coordinating to the metal atom; and
a solvent,
wherein an absolute molecular weight of the metal compound as determined by static light scattering is no less than 8,000 and no greater than 50,000.

2. The composition according to claim 1, wherein the metal compound has a structure in which two crosslinking oxygen atoms bond to the metal atom.

3. The composition according to claim 1, wherein the polydentate ligands are derived from a hydroxyacid ester, a β-diketone, a β-keto ester, a β-dicarboxylic acid ester, a hydrocarbon having a π bond, or a combination thereof.

4. The composition according to claim 1, wherein the metal atoms are metal atoms of an element type of titanium, zirconium, or a combination thereof.

5. The composition according to claim 1, wherein the solvent comprises an aliphatic monovalent alcohol having 4 or more carbon atoms, an alkylene glycol monoalkyl ether having 4 or more carbon atoms, a hydroxyacid ester having 4 or more carbon atoms, a lactone having 4 or more carbon atoms, an alkylene glycol monoalkyl ether carboxylate having 6 or more carbon atoms, or a combination thereof.

6. The composition according to claim 1, wherein the metal compound is a hydrolytic condensation product of a compound represented by formula (1):
[MLₐX_{b}] (1)
wherein, in the formula (1),
M represents a titanium atom, a tantalum atom, a zirconium atom or a tungsten atom;
L represents a polydentate ligand;
a is an integer of 1 to 3,
wherein in a case where a is no less than 2, a plurality of Ls are identical or different;
X represents a halogen ligand, a hydroxo ligand, a carboxy ligand, an alkoxy ligand, a carboxylate ligand or an amido ligand; and
b is an integer of 2 to 6,
wherein a plurality of Xs are identical or different, and
wherein a value of (a×2+b) is no greater than 6.

7. The composition according to claim 6, wherein in the formula (1), b is 2.

8. The composition according to claim 6, wherein the polydentate ligand represented by L in the formula (1) is derived from a hydroxyacid ester, a β-diketone, a β-keto ester, a β-dicarboxylic acid ester, a hydrocarbon having a π bond, or a combination thereof.

9. The composition according to claim 6, wherein in the formula (1), X represents the alkoxy ligand.

10. A pattern-forming method comprising:
applying the composition according to claim 1 on an upper face side of a substrate to form an inorganic film;
forming a resist pattern on an upper face side of the inorganic film; and
dry-etching the inorganic film and the substrate, by each separate etching operation, using the resist pattern as a mask such that the substrate has a pattern.

11. The pattern-forming method according to claim 10, wherein the forming of the resist pattern comprises:
overlaying an antireflective film on the upper face side of the inorganic film; and
forming the resist pattern on an upper face side of the overlaid antireflective film.

12. The pattern-forming method according to claim 10, further comprising forming a resist underlayer film on the substrate,
wherein in the forming of the inorganic film, the inorganic film is formed on an upper face side of the resist underlayer film.
